(19) United States
(12) Patent Application Publication
(10) Pub. No.: US 2019/0132112 A1
(43) Pub. Date: May 2, 2019

(54) PHASE CACHING FOR FAST DATA RECOVERY

(71) Applicant: Microsoft Technology Licensing, LLC, Redmond, WA (US)

(72) Inventors: Hitesh BALLANI, Cambridge (GB); Paolo COSTA, London (GB); Hugh David Paul WILLIAMS, Cambridge (GB); István HALLER, Cambridge (GB); Krzysztof JOZWIK, Cambridge (GB); Benn Charles THOMSEN, London (GB); Kari Aaron CLARK, London (GB); Adam Christopher FUNNELL, London (GB); Philip Michael WATTS, Chelmsford (GB); Kai SHI, Cambridge (GB); Thomas Michael Hoare GERARD, London (GB)

(21) Appl. No.: 15/857,321

(22) Filed: Dec. 28, 2017

(30) Foreign Application Priority Data
Oct. 27, 2017 (GB) 1717689.2

(51) Int. Cl. H04L 7/00; H04L 7/10; H04L 7/033

(52) U.S. Cl. CPC H04L 7/0025; H04L 7/10; H03L 7/07; H04L 7/0012; H04L 7/0337; H04L 7/0087

(57) ABSTRACT

There is a communications network node comprising a transmitter or a receiver configured to communicate with a plurality of other nodes via an interconnection medium interconnecting the node and the other nodes. The node is frequency synchronized with regard to signal transmission or reception, via a frequency synchronization mechanism, with at least one of the other nodes. The node has at least one store holding phase data relating to an amount of phase asynchrony and path characteristics between the node and at least one of the other nodes. A phase controller uses the stored data to adjust phase used by the node such that the recovery of data when communicating with at least one other node is facilitated.

### CROSS REFERENCE TO RELATED APPLICATION

This application claims priority to GB application serial number 1717689.2, filed Oct. 27, 2017, the entirety of which is hereby incorporated by reference herein.

### BACKGROUND

The technology generally relates to recovering data from a digital signal sent over a wired (e.g., optical or electrical) or a wireless communications network. The signal typically encodes zeros and ones and the task of recovering these zeros and ones from the signal, received at analog receiving equipment at the destination, is not straightforward where the clock of the sender is unknown. This is because it is difficult to tell where a zero begins for example, or to tell two ones apart if they are sent one immediately after the other. The task of recovering the clock of the sender and also recovering the data (zeros and ones) from the signal is typically referred to as clock and data recovery and is a well known problem. Typically the receiver has dedicated clock and data recovery (CDR) circuitry to carry out the clock and data recovery.

The embodiments described below are not limited to implementations which solve any or all of the disadvantages of known clock and data recovery systems.

### SUMMARY

The following presents a simplified summary of the disclosure in order to provide a basic understanding to the reader. This summary is not intended to identify key features or essential features of the claimed subject matter nor is it intended to be used to limit the scope of the claimed subject matter. Its sole purpose is to present a selection of concepts disclosed herein in a simplified form as a prelude to the more detailed description that is presented later.

There is a communications network node comprising a transmitter or a receiver configured to communicate with a plurality of other nodes via an interconnection medium interconnecting the node and the other nodes. The node is frequency synchronized with regard to signal transmission or reception, via a frequency synchronization mechanism, with at least one of the other nodes. The node has at least one store holding phase data relating to an amount of phase asynchrony and path characteristics between the node and at least one of the other nodes. A phase controller uses the stored data to adjust phase used by the node such that the recovery of data when communicating with at least one other node is facilitated.

In various examples, a destination node detects and stores the phase data relating to the asynchrony between itself and the sending node, which is a function of the phase difference between a clock of the destination node signal recovery process and a clock of the sending node signal transmission process, and to characteristics of the path interconnecting the destination node and sending node.

Many of the attendant features will be more readily appreciated as the same becomes better understood by reference to the following detailed description considered in connection with the accompanying drawings.

### DESCRIPTION OF THE DRAWINGS

The present description will be better understood from the following detailed description read in light of the accompanying drawings, wherein:

FIG. 1 is a schematic diagram of a communications network implementing the present technology;

FIG. 1a is a schematic diagram of a receiver of a node of the communications network of FIG. 1;

FIG. 1b is a schematic diagram of a transmitter of a node of the communications network of FIG. 1;

FIG.

FIG. 2 is a schematic diagram of a graph of transmitted data against time for the case when free running clock data recovery is used and also for the case where the present technology is used;

FIG. 3 is a flow diagram of a method at a transmitter of adjusting phase of a transmitted signal;

FIG. 4 is a flow diagram of a method at a receiver of receiving a phase adjusted signal from a transmitter;

FIG. 5 is a flow diagram of a method at a receiver of adjusting phase of a received signal;

FIG. 6 is a flow diagram of a method at a transmitter of transmitting a signal to a receiver which is carrying out phase adjustment;

FIG. 7 is a flow diagram of a method of receiver-based phase caching calibration;

FIG. 8 is a flow diagram of a method of transmitter-based phase caching calibration;

FIG. 9 is a flow diagram of a method of calibration in a case of phase adjustment at both a transmitter and a receiver;

FIG. 10 is a flow diagram of another method of calibration;

FIG. 11 is a graph of empirical data showing clock data recovery locking time against duration of execution of an example of the communications network of FIG. 1.

Like reference numerals are used to designate like parts in the accompanying drawings.

### DETAILED DESCRIPTION

The detailed description provided below in connection with the appended drawings is intended as a description of the present examples and is not intended to represent the only forms in which the present example are constructed or utilized. The description sets forth the functions of the example and the sequence of operations for constructing and operating the example. However, the same or equivalent functions and sequences may be accomplished by different examples.

As mentioned in the background section, clock and data recovery circuitry is often used at destination nodes which receive incoming signals. When a receiver receives a signal from a sender, for which the sending clock is not known by the receiver, the receiver operates its clock and data recovery circuitry in order to lock onto the signal. During the locking phase the sender sends a signal with many transitions between zeros and ones, or a signal representing a clock, to facilitate the recovery of the sending clock at the receiver clock and data recovery circuitry.

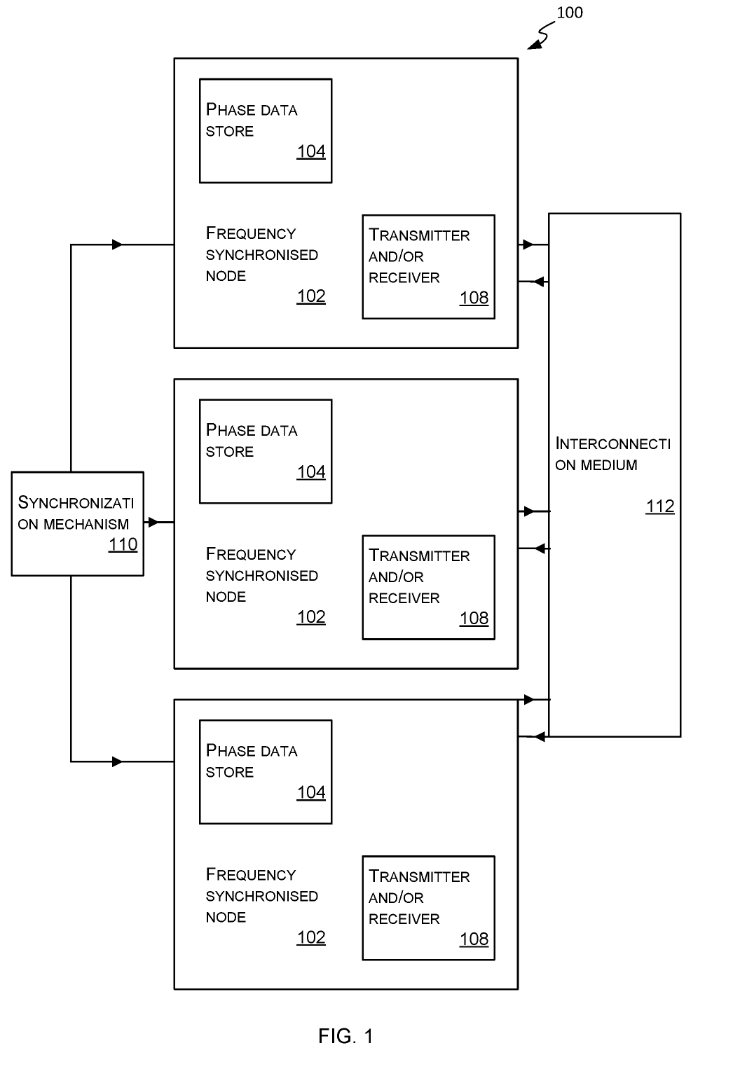

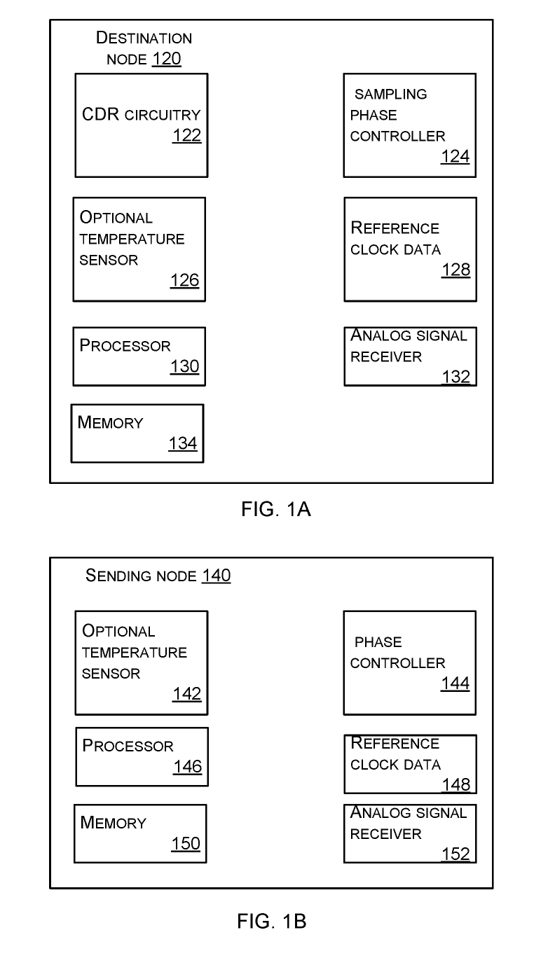

FIG. 1 is a schematic diagram of a communications network 100 implementing the present technology. The communications network 100 comprises a plurality of nodes 102 connected to one another by an interconnection medium 112 such as one or more optical and/or electrical circuit switches. In some examples, there are many hundreds or thousands of nodes but only three are shown in FIG. 1 for clarity. A circuit switch is a mechanism for connecting a specified pair of nodes of the network so that the specified nodes of the pair are changeable. In the case of an optical network the circuit switch is a high radix optical switch in some examples of the present technology. A high radix optical switch comprises thousands of ports with high per-port bandwidth (over 20 giga bits per second) and low switching latency (less than 40 nano seconds). An electric circuit switch is an electrical means for connecting a specified pair of nodes of the network so that the specified nodes of the pair is changeable.

The communications network 100 comprises a synchronization mechanism 110 which is implemented in a variety of different possible ways. In some cases the synchronization mechanism comprises a physical reference clock connected to each of the nodes 102 in a point to point fashion or connected to the nodes 102 in a hierarchical fashion. In the case of hierarchical connection the physical reference clock is directly connected to at least one of the nodes 102 and information from the reference clock is sent from the node(s) directly connected to the physical reference clock to others of the nodes. In some cases the synchronization mechanism comprises use of Synchronous Ethernet (trade mark) which is an International Telecommunication Union standard used to achieve frequency synchronization. The communications network 100 is mesochronous which means that nodes connected by the network have the same frequency but different phases.

Each node 102 comprises a transmitter and/or receiver 108 in order to transmit and/or receive signals with others of the nodes 102 over the interconnection medium 112. Where a node 102 acts to send a signal it is referred to as a sending node herein. Where a node 102 acts to receive a signal it is referred to as a destination node herein for clarity. However, a single node is able to act as a sending node and as a destination node. Because the nodes 102 are frequency synchronized the signals sent by the nodes 102 are at the same frequency. However, the phases of the signals sent by the individual nodes 102 are not synchronized. Thus the present technology is concerned with how to deal with the problem of different ones of the nodes being out of synchrony with respect to phase. Previous approaches to this problem have involved using burst-mode clock and data recovery circuitry (CDR circuitry) at destination nodes. The burst-mode CDR circuitry takes time to operate, takes power to operate and is prone to failure and inaccuracy. Also the CDR circuitry takes space in the node 102.

The present technology reduces the need and/or use of the clock and data recovery circuitry. This is achieved through the use of stored phase data 104 accessible to the nodes 102 and stored locally at one or more of the nodes 102 or stored at another location. The stored phase data is empirically derived in a calibration process or is manually configured. The stored phase data comprises one or more per-node phase values. The stored phase data comprises phase offsets to be applied to a signal before transmission, and/or sampling phase values to be used at a destination node clock and data recovery process, so that a locking phase of the clock and data recovery process at the destination node is substantially reduced or effectively eliminated. The stored phase data relates to the amount of phase asynchrony and also relates to path characteristics between one or more specified pairs of nodes of the communications network.

In the frequency-synchronized network, the clock and data recovery (CDR) circuitry at a destination node only needs to compensate for the relative phase difference of the sending node in order to start sampling the incoming bitstream almost instantaneously. This, in turn, can be achieved by caching this relative phase difference and applying it at the sending node or destination node (or both).

In an example, every sending node caches a table comprising phase values corresponding to every destination node connected to the network. The cached phase value is the transmit clock phase to be used by the sending node when sending data to the corresponding destination. By resetting the phase at each sending node at each timeslot (i.e., every time a transmission occurs between a pair of nodes), the process ensures that each destination node always receives data that is perfectly phase aligned and hence, the receiver sampling phase remains constant.

In another example, every destination node caches a table comprising phase values corresponding to every sending node connected to the network. The cached phase value is the ideal sampling point used by the destination node when receiving data from the corresponding sending node. By resetting the phase at each destination node at each timeslot (i.e., every time a transmission occurs between a pair of nodes), the process ensures that each destination node is perfectly phase aligned to the incoming data instantaneously. This is used in case of broadcast/multicast transmission where destination nodes independently select their correct phase based on the source of the broadcast/multicast transmission.

In another example, hybrid phase caching is used. This involves each sending node caching a table of phase value for all destination nodes and every destination node caching a table of phase values for all sending nodes. In effect, the hybrid technique allows the phase adjustment needed between a pair of nodes to be divided across the sending node and the destination node. The cached adjustments for a given pair of nodes are such that, when the sending node adjusts its transmit clock phase according to its cache and the destination node adjusts its sampling phase according to its cache, the destination node is perfectly phase aligned to the incoming data instantaneously.

Alternative approaches which seek to improve CDR circuitry to reduce the phase locking times are found to give expensive and invasive hardware mechanisms and in some cases to reduce stability of the acquired phase lock.

FIG. 1A shows one of the nodes 102 of FIG. 1 where the node is a destination node 120. It comprises clock and data recovery circuitry 122 and a sampling phase controller 124 which is able to change a sampling phase used by the clock and data recovery circuitry 122 to recover data from an incoming signal. The sampling phase controller 124 is circuitry able to operate with low latency in preferred embodiments of the technology. In one example, which is not intended to limit the scope of the technology, the sampling phase controller 124 is a phase interpolator (PI) of a PI-based CDR architecture which allows for fine tuning at a fraction of the bit period granularity, of the sampling clock phase. The destination node 120 optionally comprises a temperature sensor 126. The destination node has a reference clock source 128 from the synchronization mechanism 110. It also comprises a processor 130, a memory 134 and an analog signal receiver 132.

FIG. 1B shows one of the nodes 102 of FIG. 1 where the node is a sending node 140. It is the same as the destination node 120 except that the CDR circuitry 122 is absent and the analog signal receiver 132 is replaced by an analog signal transmitter 152. Also, the sampling phase controller 124 is now a phase controller 144 which is circuitry to adjust the phase of an analog signal transmitted by the analog signal transmitter 152. In one example, which is not intended to limit the scope of the technology, the phase controller 144 is a phase interpolator (PI) controller of a transceiver architecture which allows for fine tuning at a fraction of the bit period granularity, of the phase of the transmitted signal.

The sending node 140 has a reference clock source 148, a memory 150, a processor 146 and an optional temperature sensor 142.

In some, but not all examples of the present technology, the interconnection medium switches between different ones of the nodes in a fast, time slotted manner. That is, at each time slot the interconnection medium switches at least one of the destination nodes off its current sending node and onto a different sending node. The destination node does not know the phase of the signals of the different sending nodes. Thus if it uses conventional clock and data recovery, it spends significant time (around five micro seconds) locking onto the correct phase. In the meantime the next time slot occurs (for example the time slots are every 50 nano seconds) and so the end result is a non-working system. The present technology enables the time to lock onto the correct phase to be significantly reduced or eliminated so that the destination node is able to recover the data even with switching at every time slot (where the time slots are smaller or of similar magnitude to the phase locking time). Such fast switching is critical to support latency-sensitive workloads atop the communications network, such as where the communications network is within a data center.

The communications network comprises an arbitration mechanism in some examples. The arbitration mechanism comprises one or more rules, thresholds or criteria used to enable resolution of contention or conflict between nodes, such as when a given sending node is connected to two different destination nodes by the interconnection medium.

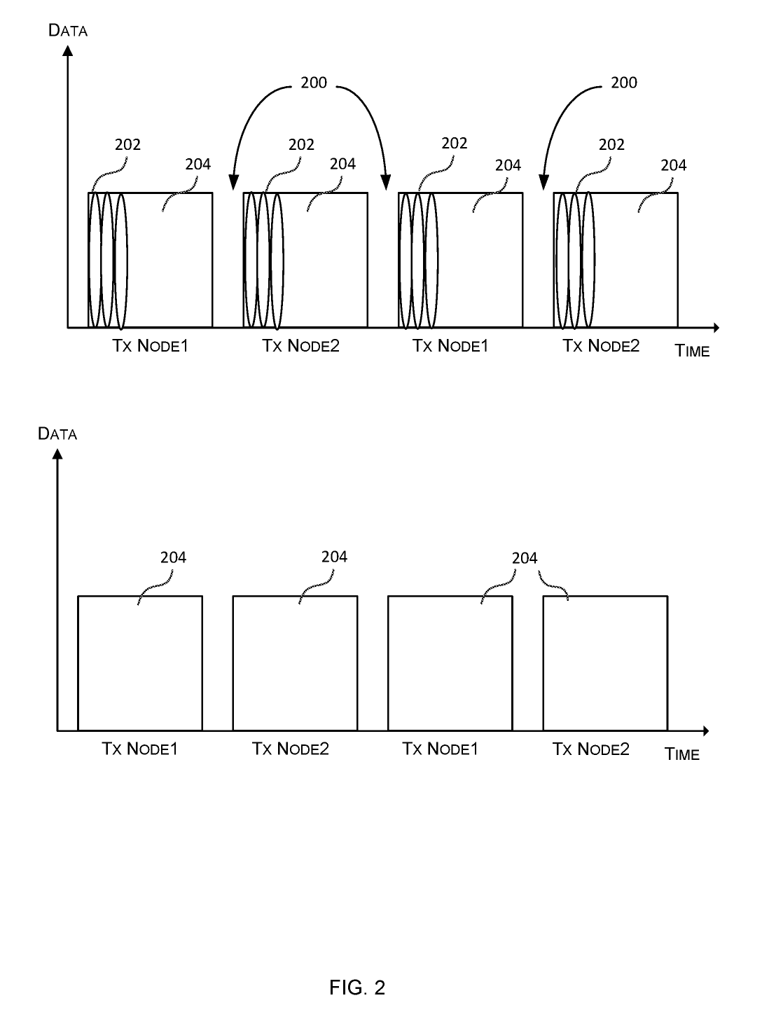

FIG. 2 is a schematic diagram included to aid understanding of the present technology. FIG. 2 shows an amount of data recovered at a destination node from a first sending node (Tx node 1) and from a second sending node (Tx node 2) over time. Bursts of data are sent with one burst per time slot, and with alternation between the first and second sending nodes. The sending nodes operate at the same frequency (due to frequency synchronization) and the bursts of data from each sending node are separated by the same time interval. A guard band 200 which is a time interval with no transmission occurs between the bursts.

In the upper graph a conventional free-running clock and data recovery process is being used at the destination node. Here there is a phase locking period 202 at the start of each burst and data is recovered during interval 204 of each burst.

In the lower graph the present technology is used. Here there is no phase locking period and the interval in which data is recovered 204 is larger for each burst than in the case of the upper graph.

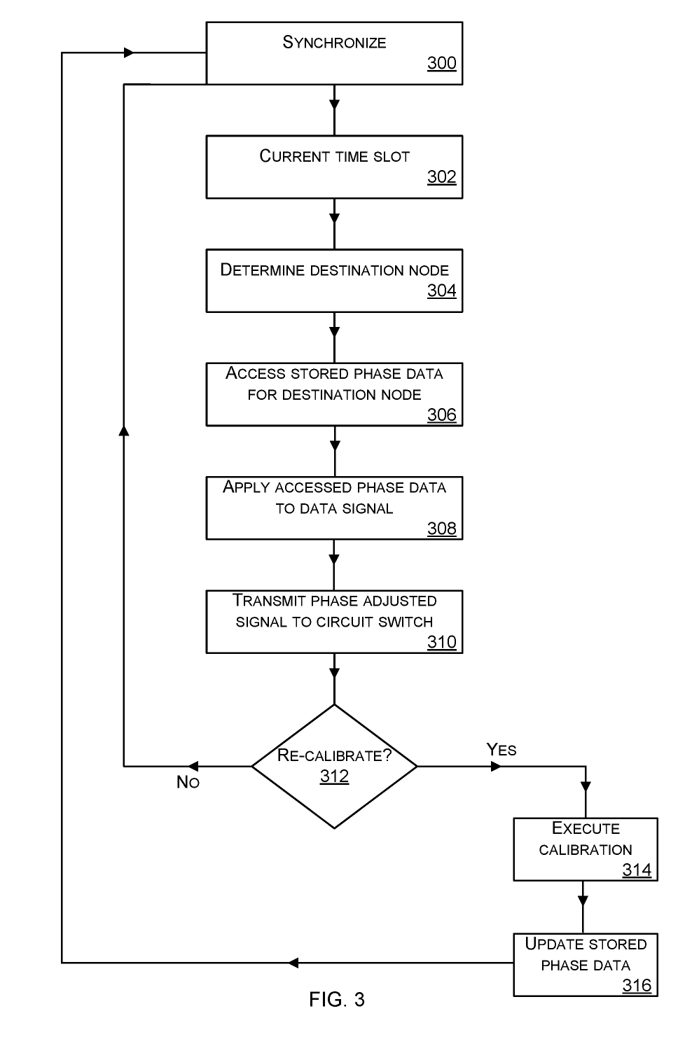

FIG. 3 is a flow diagram of a method implemented at a transmitter at one of the nodes of the communications network of FIG. 1. The transmitter is synchronized 300 using the synchronization mechanism which is any of the synchronization mechanisms mentioned above. At the current time slot 302 where a time slot is a time interval measured in the units of a clock with frequency synchronized by the frequency synchronization mechanism, the transmitter determines 304 which destination node it is to transmit to. This is determined using a rule or allocation scheme known to the transmitter, or in any other suitable way. In an example, a round robin allocation scheme is used and is known by each node of the communications network and the arbitration mechanism. In another example, the transmitter is informed of the identity of the destination node by receiving this information from the arbitration mechanism

The transmitter accesses 306 stored phase data for the destination node. This is done by looking up stored phase data for the destination node in a store local to the transmitter or accessible to the transmitter from a location remote of the transmitter. In a preferred example, the stored phase data is in a cache at the transmitter. The stored phase data for the destination node is a phase value which expresses the phase offset between transmissions from the transmitter and a sampling phase of a data recovery process at the receiver. The stored phase data is per node stored phase data. The stored phase data is obtained empirically and/or configured manually.

The transmitter applies 308 the accessed phase data to the signal in order to adjust the phase of the transmitted signal to take into account the phase offset. Thus when the signal arrives at the destination node there is no need for the destination node to search for a suitable sampling phase to use in the data recovery process. The phase of the transmitted signal is adjusted using a phase controller comprising electronic circuitry as described above. In some examples the phase controller has low latency. This is especially useful where the circuit switch switches between the nodes with high frequency.

The transmitter transmits 310 the phase adjusted signal to the circuit switch and the signal is routed from there to the destination node over the communications network.

The transmitter checks 312 whether recalibration of the stored phase data for the destination node is to be done. The check 312 comprises one or more of: checking if a time interval has elapsed, checking if a request for recalibration has been received from the destination node, checking if a temperature change is detected. Other criteria or rules are used in some cases for the check 312. If no recalibration is to be done the transmitter repeats the method of FIG. 3 as indicated in the figure. If recalibration is to be done the transmitter executes a calibration process 314 and updates 316 the stored phase data. Any suitable calibration process is used and various examples are described later in this document. Once the stored phase data is updated 316 the method of FIG. 3 repeats.

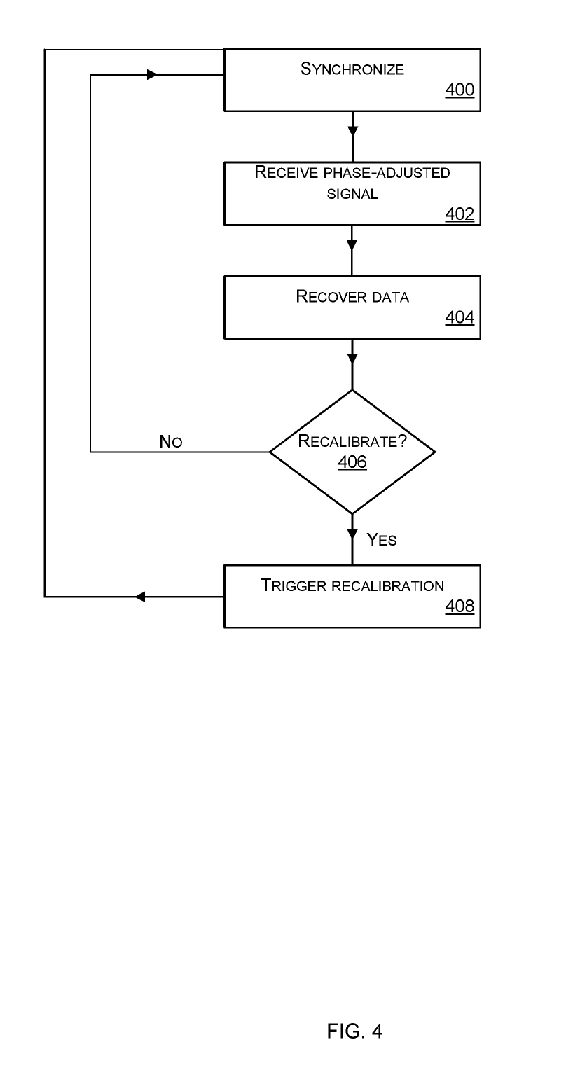

The process at the destination node is now described, in the case that the method of FIG. 3 is used at the transmitter. With reference to FIG. 4, the destination node is synchronized 400 as for the transmitter using any of the synchronization processes described herein. The destination node receives a phase adjusted signal 402 from the transmitter and is able to lock onto the signal from the transmitter in no or negligible time and with no or little need for a clock and data recovery locking phase. The destination node is thus able to immediately begin to recover the data 404 from the received signal. The destination node checks 406 whether to trigger recalibration of the stored phase data. The check comprises any one or more of: checking if a specified time interval has elapsed, checking if a bit error rate of the recovered data is above a threshold, checking if a temperature of the destination node has changed, checking if a request for recalibration has been received from a user or from the transmitter. If recalibration is to go ahead the destination node triggers 408 a recalibration process. Any suitable recalibration process is used and examples are given later in this document. The method then repeats as indicated in FIG. 4. If no recalibration is to be done at check 406 the method repeats as indicated in FIG. 4.

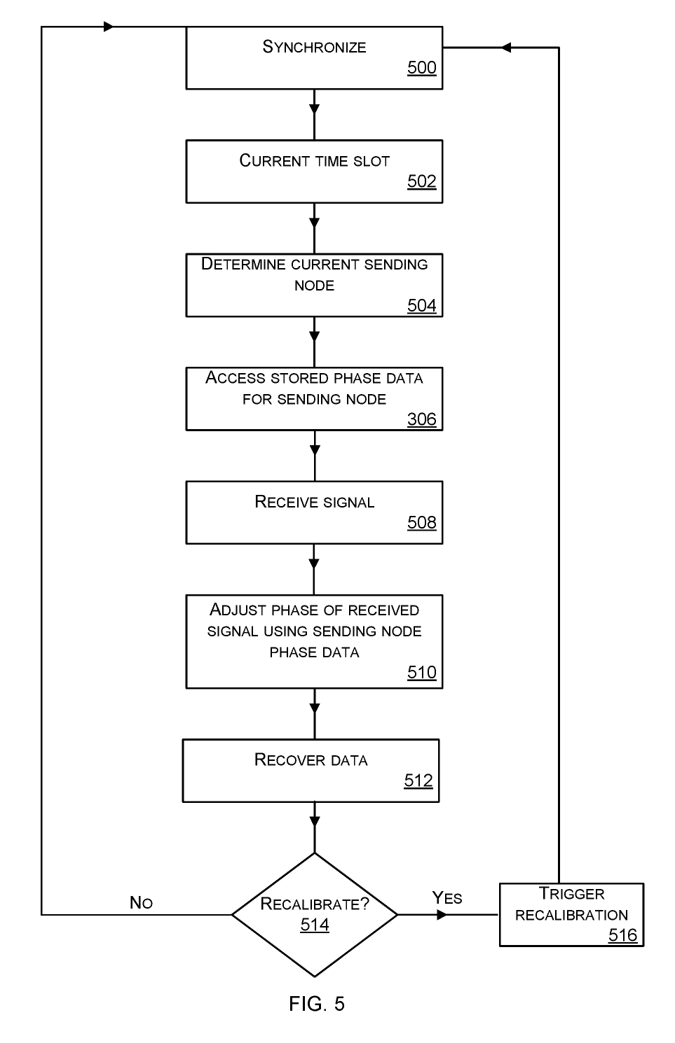

FIG. 5 is a flow diagram of an example method where the destination node adjusts the sampling phase of the received signal, rather than the transmitter adjusting the phase. The destination node is synchronized 500 using any of the synchronization mechanisms described herein. This ensures that the destination node knows the frequency of the signal it will receive.

At the current timeslot 502 the destination node determines 504 the current sending node. This is determined using a rule or allocation scheme known to the destination node, or in any other suitable way. In an example, a round robin allocation scheme is used and is known by each node of the communications network and the arbitration mechanism. In another example, the destination node is informed of the identity of the sending node by receiving this information from the arbitration mechanism.

The destination node accesses 506 stored phase data for the sending node. The stored phase data comprises a sampling phase the destination node is to use in order to take into account any offset in phase of the signal sent by the sending node and a sampling phase used by the destination node. The destination node adjusts 508 the sampling phase of its data recovery process, using the accessed stored phase data. The destination node then receives 510 a signal from the sending node transmitted over the communications network and is able to recover data 512 from the received signal. This is done without the destination node having to carry out phase locking onto the received signal.

The destination node checks 514 whether to recalibrate or not. The check 514 comprises any one or more of: checking if a specified time interval has elapsed, checking if a bit error rate of the recovered data is above a threshold, checking if a temperature of the destination node has changed, checking if a request for recalibration has been received from a user or from the transmitter. If recalibration is to go ahead the destination node triggers 516 a recalibration process. Any suitable recalibration process is used and examples are given later in this document. The method then repeats as indicated in FIG. 5. If no recalibration is to be done at check 516 the method repeats as indicated in FIG. 5.

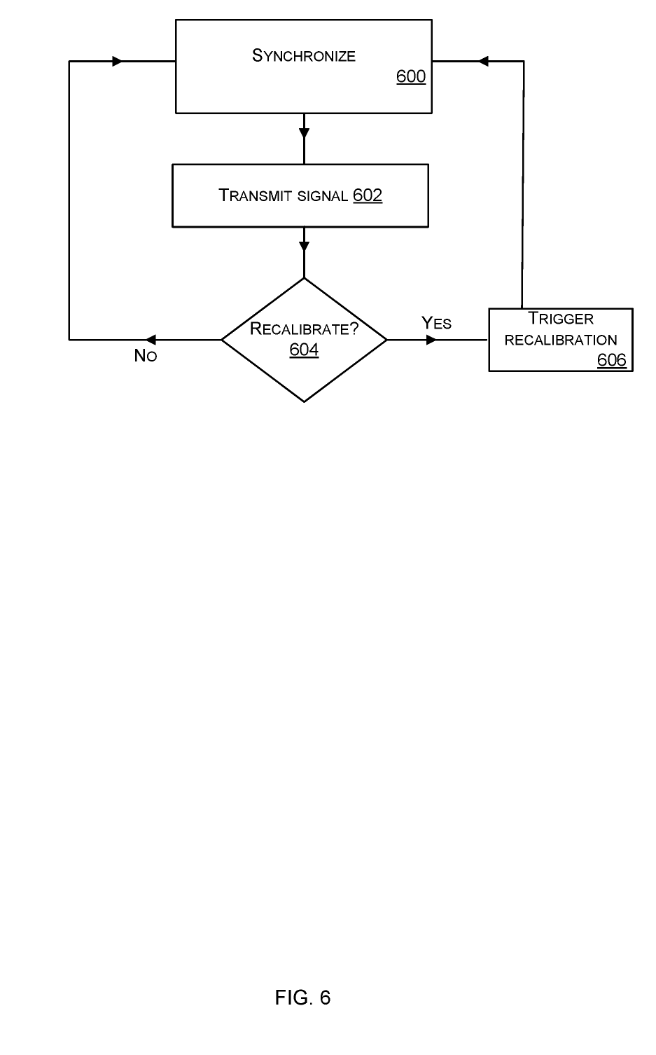

FIG. 6 is a flow diagram of a method at the sending node in the case that the destination node operates the method of FIG. 5. Here the sending node is synchronized 600 using any of the synchronization mechanisms described herein. The sending node transmits a signal to the circuit switch 602 and from there the signal is routed to the destination node. The sending node does not need to make any modification to phase of the signal since this is handled at the destination node. The sending node checks 604 whether to recalibrate. The check 604 comprises any one or more of: checking if a specified time interval has elapsed, checking if a temperature of the destination node has changed, checking if a request for recalibration has been received from a user or from the transmitter. If recalibration is to go ahead the destination node triggers 606 a recalibration process. Any suitable recalibration process is used and examples are given later in this document. The method then repeats as indicated in FIG. 6. If no recalibration is to be done at check 604 the method repeats as indicated in FIG. 6.

The methods of FIGS. 3 to 4 are for the case where the sending node adjusts the phase of the transmitted signal using stored phase data and the destination node makes no use of the stored phase data. The methods of FIGS. 5 to 6 are for the case where the destination node adjusts the sampling phase of the received signal but the sending node makes no use of the stored phase data. It is also possible to have a hybrid of these methods. That is, part of the phase adjustment is done at the sending node and part of the phase adjustment is done at the destination node. The proportion of the phase adjustment to be done by each party is agreed in advance.

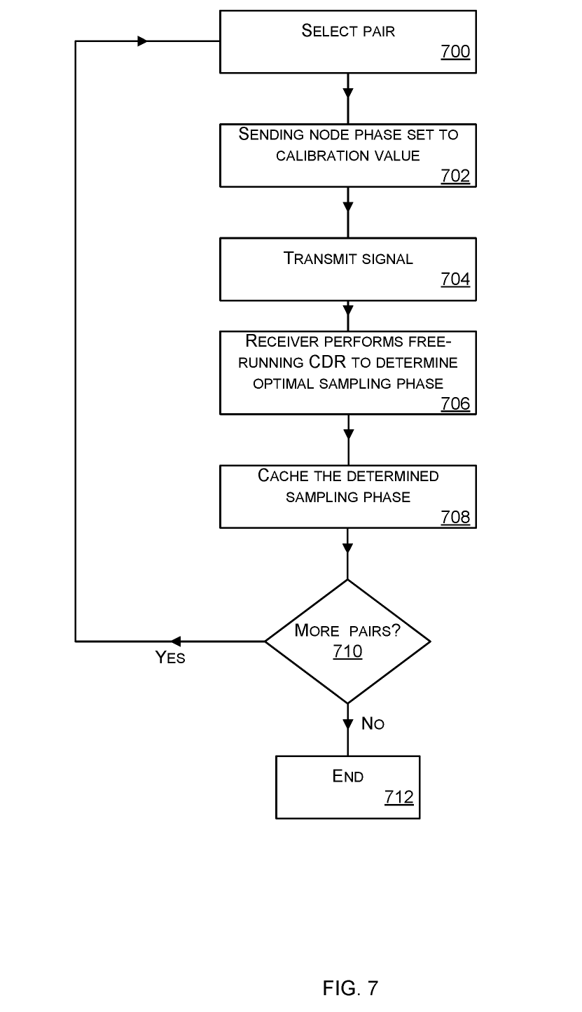

More detail about the calibration process is now given with reference to FIGS. 7 to 10.

FIG. 7 is a flow diagram of a method of calibration (in the case of destination node phase caching). A sending node and destination node pair is selected 700 from the possible pairs available in the communications network. The phase used by the sending node to transmit signals is set 702 to an initial value used for calibration. The sending node then transmits 704 a signal to the destination node.

The destination node receives the signal and performs 706 a free-running clock and data recovery process to determine an optimal sampling phase to be used for recovering the data from the received signal. The clock and data recovery process is “free-running” in that it is not influenced by any stored phase data in the same way as other data recovery processes described herein. The determined sampling phase is stored, at a cache at the destination node, or at any other location accessible to the destination node and/or sending node.

A check is made 710 to see if more pairs of nodes are available to be calibrated and if so, the method of FIG. 7 repeats for the next pair of sending and destination nodes. If all the pairs of nodes that are to be calibrated have been processed by the method of FIG. 7, or if other stopping criteria are met, the process ends 712.

When calibration has been done as described above with reference to FIG. 7 the sending node sends signals to a destination node using the calibration phase according to the method of FIG. 6. The destination node is then able to access the stored phase data and use this to select the sampling phase and thus effectively eliminate the need for a clock and data recovery locking phase (see FIG. 5).

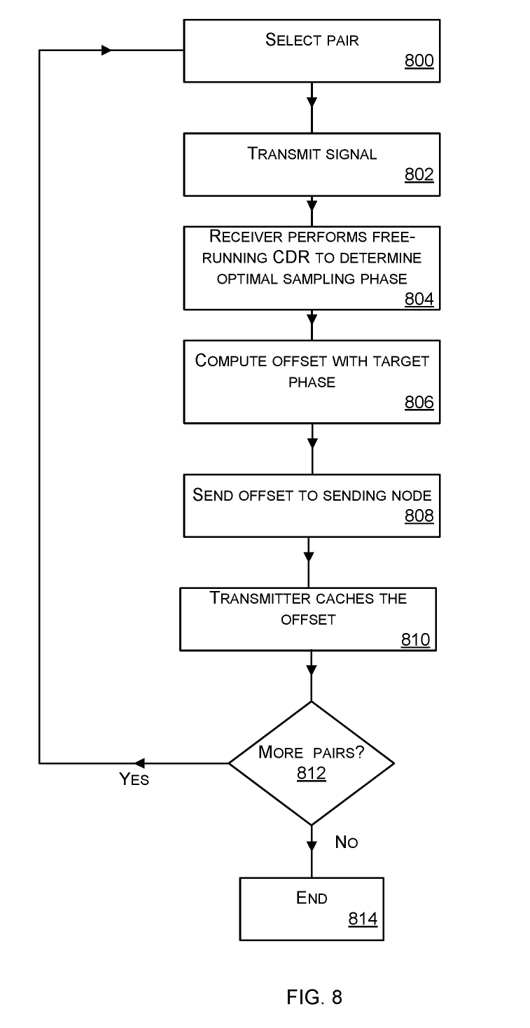

FIG. 8 is a flow diagram of another method of calibration (for sending node based phase caching). A sending node and destination node pair is selected 800 from the possible pairs available in the communications network. The phase used by the sending node to transmit signals is set to a calibration value. The sending node then transmits 802 a signal to the destination node. The destination node performs 804 free-running clock and data recovery to determine an optimal sampling phase at which to sample the incoming signal. The destination node computes 806 an offset between the optimal data sampling phase computed by the free-running clock and data recovery process and the initial phase value set for the free-running clock when no data is sampled. The initial value is the same for all the nodes and represents the offset with respect to the frequency synchronized clock source. The offset value is used to calibrate the sending node.

The computed offset is sent 808 to the sending node which stores the offset in association with an identifier of the destination node. The offset is stored in a cache at the sending node, or in any store accessible to the sending node and/or receiving node.

A check is made 801 to see if more pairs of nodes are available to be calibrated and if so, the method of FIG. 8 repeats for the next pair of sending and destination nodes. If all the pairs of nodes that are to be calibrated have been processed by the method of FIG. 8, or if other stopping criteria are met, the process ends 814.

When calibration has been done as described above with reference to FIG. 8 the sending node sends signals to a destination node using the initial phase value adjusted by the offset specified in the stored phase data according to the method of FIG. 3. The destination node is then able to eliminate the need for a clock and data recovery locking phase (see FIG. 4).

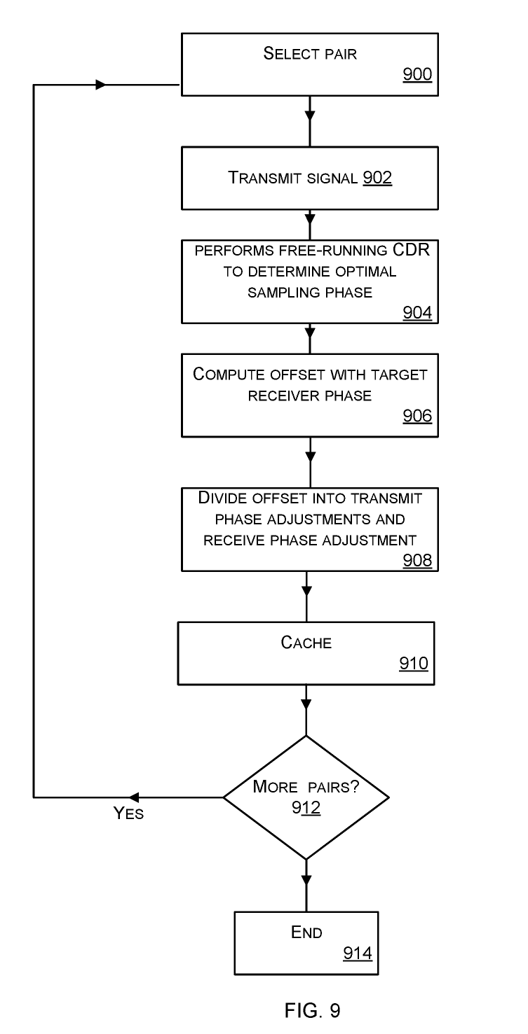

FIG. 9 is a flow diagram of another method of calibration. A sending node and destination node pair is selected 900 from the possible pairs available in the communications network. The phase used by the sending node to transmit signals is set to an initial value. The sending node then transmits 902 a signal to the destination node. The destination node performs 904 free-running clock and data recovery to determine an optimal sampling phase at which to sample the incoming signal. The destination node computes 906 an offset between the optimal data sampling phase and the initial phase value set for the free-running clock when no data is sampled. The initial value is the same for all the nodes and represents the offset with respect to the frequency synchronized clock source. The offset value is used to calibrate the destination node and the sending node.

The destination node divides the offset into a transmit phase adjustment and a receive phase adjustment according to an agreed proportion of the offset for the sending node and the destination node. The divided offset data is stored with the transmit phase adjustment values stored local to the sending node, and the receive phase adjustment values stored local to the destination node.

A check is made 912 to see if more pairs of nodes are available to be calibrated and if so, the method of FIG. 9 repeats for the next pair of sending and destination nodes. If all the pairs of nodes that are to be calibrated have been processed by the method of FIG. 9, or if other stopping criteria are met, the process ends 914.

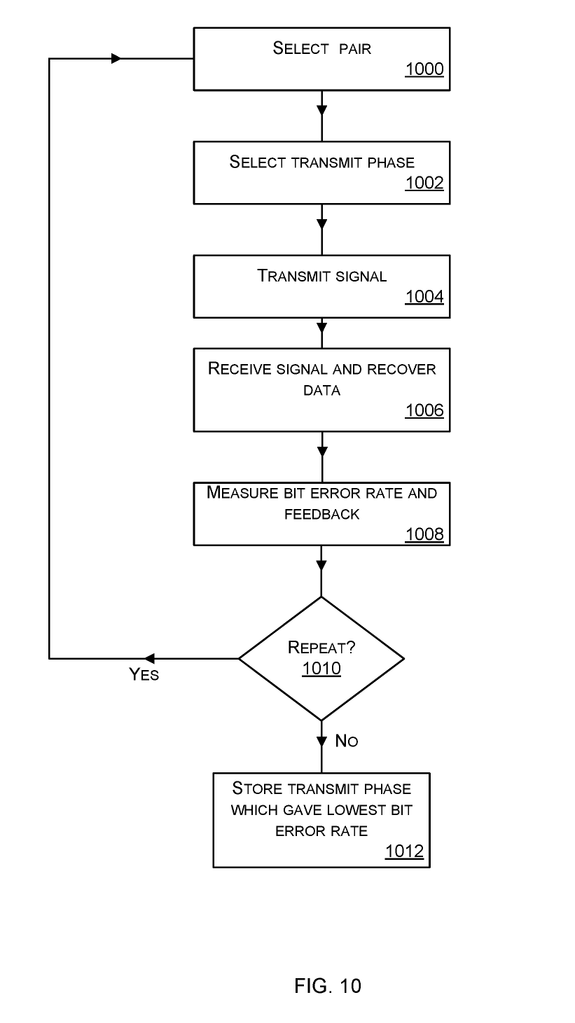

FIG. 10 is a flow diagram of another method of calibration. A sending node and destination node pair is selected 1000 from the possible pairs available in the communications network. The phase used by the sending node to transmit signals is set 1002 to a specified value in a range of possible values. The sending node transmits 1004 a signal to the destination node. The destination node recovers 1006 the data from the signal it receives using a free running clock and data recovery process on the received signal. The destination node measures 1008 a bit error rate of the recovered data, for example, where the signal comprises data which has been encoded using an error correction scheme it is possible for the destination node to compute the bit error rate. The destination node provides feedback to the sending node regarding the observed bit error rate. A check 1010 is made as to whether to repeat the method of FIG. 10 for another phase value of the range of phase values to be used by the sending node. If all the phase values of the range have been tested, or if a phase value giving a bit error rate below a specified threshold has already been found, the method stops repeating. The phase value which resulted in the lowest bit error rate is then stored 1012. Otherwise, if there is another phase value to be tested, the method repeats from operation 1000.

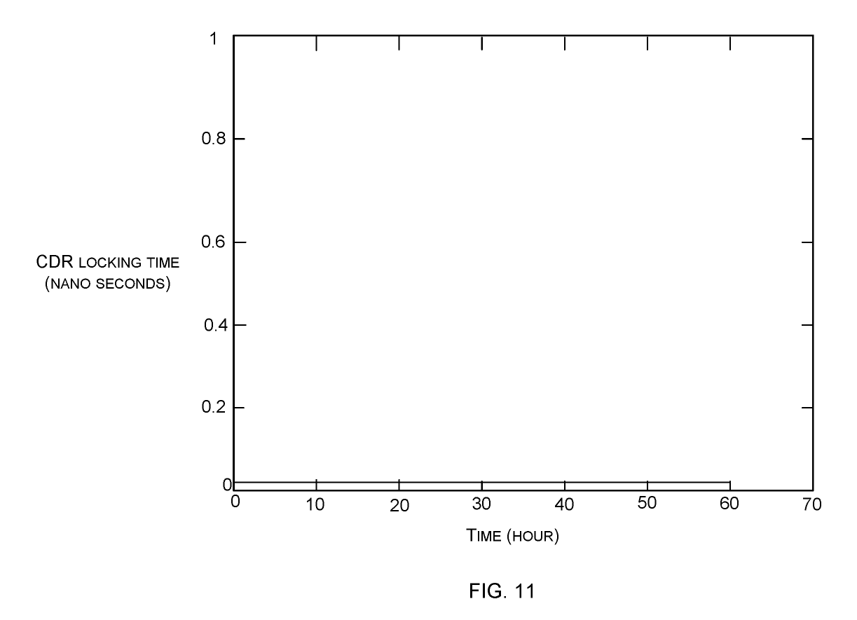

FIG. 11 is a graph of clock and data recovery locking time against time of operation of a communications network, in the case that the nodes of the communications network implement the methods described herein which use stored phase data. FIG. 11 shows data observed empirically from a physical communications network implemented as described below for one example, which is not intended to limit the scope of the technology. Rather the example below and the associated empirical data in FIG. 11 are included herein to demonstrate that the technology works and provides significant improvements in clock and data recovery locking time in a manner which is robust over time.

The empirical data of FIG. 11 was obtained using a communications network comprising commercial 25 giga bits per second (Gbps) transceivers, with two transmitting field programmable gate arrays (FPGAs) sending bursts of data to the same destination FPGA. The synchronization mechanism in this case comprises reference clock inputs for each transceiver synchronized from a single low frequency, high bandwidth 156.25 mega Hertz (MHz) programmable clock source, distributed using coaxial cables. Within each transceiver the 156.25 MHz reference clocks are multiplied up to a 12.5 GHz double data rate (DDR) clock using an integrated tank phase locked loop to transmit and receive serial data. In each timeslot, a burst of data is transmitted from a 25 Gbps transceiver and modulated onto a laser output using a Mach-Zehnder (MZ) modulator. A guard band of 20.48 ns is present between pseudo random binary sequence (PRBS) transmissions.

A phase caching system has been built on the FPGAs. The transmitter phase interpolation module within the transceiver is used to shift the transmit clock phase for the transmitting FPGAs to their cached phases values, alternating between the values each timeslot. The receiver clock and data recovery (CDR) phase value at the end of each packet is observed for each transmitter, and the difference between this phase and a receiver CDR phase offset of zero with respect to the receiver reference clock is used to correct the transmitter phases so that all packets arrive with a receiver CDR phase of zero. When the communications network was run for a duration of 60 hours it was found that the CDR locking time in nanoseconds remained close to zero. This demonstrates the effectiveness of the present technology in effectively eliminating CDR locking time.

Each node 102 of the communications network of FIG. 1 comprises one or more processors 130, 146 which are microprocessors, controllers or any other suitable type of processors for processing computer executable instructions to control the operation of the device in order to implement the technology described herein. In some examples, for example where a system on a chip architecture is used, the processors 130, 146 include one or more fixed function blocks (also referred to as accelerators) which implement a part of the method of FIGS. 3 to 10 in hardware (rather than software or firmware).

The computer executable instructions are provided using any computer-readable media that is accessible by node 102. Computer-readable media includes, for example, computer storage media such as memory 134, 150 and communications media. Computer storage media, such as memory 134, 150, includes volatile and non-volatile, removable and non-removable media implemented in any method or technology for storage of information such as computer readable instructions, data structures, program modules or the like. Computer storage media includes, but is not limited to, random access memory (RAM), read only memory (ROM), erasable programmable read only memory (EPROM), electronic erasable programmable read only memory (EEPROM), flash memory or other memory technology, compact disc read only memory (CD-ROM), digital versatile disks (DVD) or other optical storage, magnetic cassettes, magnetic tape, magnetic disk storage or other magnetic storage devices, or any other non-transmission medium that is used to store information for access by a computing device. In contrast, communication media embody computer readable instructions, data structures, program modules, or the like in a modulated data signal, such as a carrier wave, or other transport mechanism. As defined herein, computer storage media does not include communication media. Therefore, a computer storage medium should not be interpreted to be a propagating signal per se. Although the computer storage media (memory 134, 150) is shown within the node 102, 120, 140 it will be appreciated that the storage is, in some examples, distributed or located remotely and accessed via a network or other communication link (e.g. using interconnection medium 112).

Alternatively or in addition to the other examples described herein, examples include any combination of the following:

A communications network comprising:

a plurality of nodes connected to one another via an interconnection medium;

a frequency synchronizing mechanism configured to synchronize a signal frequency of at least two of the nodes, being a sending node and a destination node;

at least one store holding phase data relating to an amount of phase asynchrony and path characteristics between at least the sending node and the destination node;

a phase controller configured to use the stored data to adjust phase used by at least one of the sending node and the destination node such that recovery of data from a signal transmitted between the sending node and the destination node is facilitated.

The communications network described above wherein the stored phase data comprises phase offsets to be applied to a signal before transmission, and/or sampling phase values to be used at a destination node clock and data recovery process.

The communications network described above wherein the stored phase data has been determined empirically in a calibration process.

The communications network described above wherein the frequency synchronization mechanism synchronizes the plurality of nodes of the communications network and where the store holds phase data relating to an amount of phase asynchrony and path characteristics between a plurality of pairs of the nodes.

The communications network described above wherein the frequency synchronization mechanism comprises one or more of:
a reference clock connected to the plurality of nodes in a point to point manner or in a hierarchical manner;
a clock signal transfer process.

The communications network described above wherein the interconnection medium is configured to switch between different ones of the nodes in a time slotted manner, such that at each time slot the interconnection medium switches at least one of the destination nodes off its current sending node and onto a different sending node.

A communications network node comprising:

a transmitter or a receiver configured to communicate with a plurality of other nodes via an interconnection medium interconnecting the node and the other nodes;

the node being frequency synchronized with regard to signal transmission or reception, via a frequency synchronization mechanism with at least one of the other nodes;

at least one store holding phase data relating to an amount of phase asynchrony and path characteristics between the node and at least one of the other nodes;

a phase controller configured to use the stored data to adjust phase used by the node such that recovery of data when communicating with the at least one other node is facilitated.

The communications network node described above wherein the stored phase data comprises phase offsets to be applied to a signal before transmission, and/or sampling phase values to be used at a destination node clock and data recovery process.

A method in a communications network comprising a plurality of nodes connected to one another via an interconnection medium, the method comprising:

operating a frequency synchronizing mechanism to synchronize a signal frequency of at least two of the nodes, being a sending node and a destination node;

storing phase data relating to an amount of phase asynchrony and path characteristics between at least the sending node and the destination node;

using the stored data to adjust phase used by at least one of the sending node and the destination node such that recovery of data from a signal transmitted between the sending node and the destination node is facilitated.

The method described above wherein using the stored data to adjust the phase comprises adjusting the phase of a signal and then transmitting the signal from a sending node of the plurality of nodes.

The method described above wherein using the stored data to adjust the phase comprises adjusting a sampling phase of a clock and data recovery process.

The method described above comprising using a calibration process to obtain the stored phase data.

The method described above wherein the calibration process comprises transmitting, for each of a plurality of phases, a signal from the sending node to the receiving node, and observing a bit error rate of a recovered signal at the destination node, for each of the plurality of phases; and storing the phase associated with a lowest bit error rate.

The method described above wherein the calibration process comprises transmitting a signal with a calibration phase from the sending node to the receiving node, and performing a free-running clock and data recovery process on the received signal to determine an optimal sampling phase of the clock and data recovery process.

The method described above wherein the calibration process comprises storing the optimal sampling phase in association with an identifier of the destination node.

The method described above wherein the calibration process comprises computing an offset between the determined optimal sampling phase and a target phase of the destination node.

The method described above wherein the calibration process comprises computing an offset between the determined optimal sampling phase and a target phase of the destination node and dividing the offset into a transmit phase adjustment and a receive phase adjustment and caching the transmit phase adjustment at the sending node and caching the receive phase adjustment at the destination node.

The method described above comprising:
using the interconnection medium to switch between pairs of the nodes in a time slotted manner;
operating the frequency synchronizing mechanism to synchronize a signal frequency of the plurality of nodes;
storing phase data relating to an amount of phase asynchrony and path characteristics between each of a plurality of pairs of the nodes;
using the stored data to adjust phase used by the nodes such that recovery of data is facilitated.

The method described above wherein the time slots of the interconnection medium have an interval which is of the same magnitude as a phase locking interval of a clock and data recovery process of at least one of the nodes with respect to the signal.

The method described above comprising triggering the calibration process if one or more of the following applies: if a specified time interval has elapsed, if a bit error rate of the recovered data is above a threshold, if a temperature of the destination node has changed, if a request for recalibration has been received from a user or from another node.

The term ‘computer’ or ‘computing-based device’ is used herein to refer to any device with processing capability such that it executes instructions. Those skilled in the art will realize that such processing capabilities are incorporated into many different devices and therefore the terms ‘computer’ and ‘computing-based device’ each include personal computers (PCs), servers, mobile telephones (including smart phones), tablet computers, set-top boxes, media players, games consoles, personal digital assistants, wearable computers, and many other devices.

The methods described herein are performed, in some examples, by software in machine readable form on a tangible storage medium e.g. in the form of a computer program comprising computer program code means adapted to perform all the operations of one or more of the methods described herein when the program is run on a computer and where the computer program may be embodied on a computer readable medium. The software is suitable for execution on a parallel processor or a serial processor such that the method operations may be carried out in any suitable order, or simultaneously.

This acknowledges that software is a valuable, separately tradable commodity. It is intended to encompass software, which runs on or controls “dumb” or standard hardware, to carry out the desired functions. It is also intended to encompass software which “describes” or defines the configuration of hardware, such as HDL (hardware description language) software, as is used for designing silicon chips, or for configuring universal programmable chips, to carry out desired functions.

Any range or device value given herein may be extended or altered without losing the effect sought, as will be apparent to the skilled person.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item refers to one or more of those items.

The operations of the methods described herein may be carried out in any suitable order, or simultaneously where appropriate. Additionally, individual blocks may be deleted from any of the methods without departing from the scope of the subject matter described herein. Aspects of any of the examples described above may be combined with aspects of any of the other examples described to form further examples without losing the effect sought.

The term ‘comprising’ is used herein to mean including the method blocks or elements identified, but that such blocks or elements do not comprise an exclusive list and a method or apparatus may contain additional blocks or elements.

The term ‘subset’ is used herein to refer to a proper subset such that a subset of a set does not comprise all the elements of the set (i.e. at least one of the elements of the set is missing from the subset).

It will be understood that the above description is given by way of example only and that various modifications may be made by those skilled in the art. The above specification, examples and data provide a complete description of the structure and use of exemplary embodiments. Although various embodiments have been described above with a certain degree of particularity, or with reference to one or more individual embodiments, those skilled in the art could make numerous alterations to the disclosed embodiments without departing from the scope of this specification.

1. A communications network comprising:
a plurality of nodes connected to one another via an interconnection medium;
a frequency synchronizing mechanism configured to synchronize a signal frequency of at least two of the nodes, being a sending node and a destination node;
at least one store holding phase data relating to an amount of phase asynchrony and path characteristics between at least the sending node and the destination node;
a phase controller configured to use the stored data to adjust phase used by at least one of the sending node and the destination node such that recovery of data from a signal transmitted between the sending node and the destination node is facilitated.

2. The communications network of claim 1 wherein the stored phase data comprises phase offsets to be applied to a signal before transmission, and/or sampling phase values to be used at a destination node clock and data recovery process.

3. The communications network of claim 1 wherein the stored phase data has been determined empirically in a calibration process.

4. The communications network of claim 1 wherein the frequency synchronization mechanism synchronizes the plurality of nodes of the communications network and where the store holds phase data relating to an amount of phase asynchrony and path characteristics between a plurality of pairs of the nodes.

5. The communications network of claim 4 wherein the frequency synchronization mechanism comprises one or more of:
a reference clock connected to the plurality of nodes in a point to point manner or in a hierarchical manner;
a clock signal transfer process.

6. The communications network of claim 1 wherein the interconnection medium is configured to switch between different ones of the nodes in a time slotted manner, such that at each time slot the interconnection medium switches at least one of the destination nodes off its current sending node and onto a different sending node.

7. A communications network node comprising:
a transmitter or a receiver configured to communicate with a plurality of other nodes via an interconnection medium interconnecting the node and the other nodes;
the node being frequency synchronized with regard to signal transmission or reception, via a frequency synchronization mechanism with at least one of the other nodes;
at least one store holding phase data relating to an amount of phase asynchrony and path characteristics between the node and at least one of the other nodes;
a phase controller configured to use the stored data to adjust phase used by the node such that recovery of data when communicating with the at least one other node is facilitated.

8. The communications network node of claim 7 wherein the stored phase data comprises phase offsets to be applied to a signal before transmission, and/or sampling phase values to be used at a destination node clock and data recovery process.

9. A method in a communications network comprising a plurality of nodes connected to one another via an interconnection medium, the method comprising:
operating a frequency synchronizing mechanism to synchronize a signal frequency of at least two of the nodes, being a sending node and a destination node;
storing phase data relating to an amount of phase asynchrony and path characteristics between at least the sending node and the destination node;
using the stored data to adjust phase used by at least one of the sending node and the destination node such that recovery of data from a signal transmitted between the sending node and the destination node is facilitated.

10. The method of claim 9 wherein using the stored data to adjust the phase comprises adjusting the phase of a signal and then transmitting the signal from a sending node of the plurality of nodes.

11. The method of claim 9 wherein using the stored data to adjust the phase comprises adjusting a sampling phase of a clock and data recovery process.

12. The method of claim 9 comprising using a calibration process to obtain the stored phase data.

13. The method of claim 12 wherein the calibration process comprises transmitting, for each of a plurality of phases, a signal from the sending node to the receiving node, and observing a bit error rate of a recovered signal at the destination node, for each of the plurality of phases; and storing the phase associated with a lowest bit error rate.

14. The method of claim 12 wherein the calibration process comprises transmitting a signal with a calibration phase from the sending node to the receiving node, and performing a free-running clock and data recovery process on the received signal to determine an optimal sampling phase of the clock and data recovery process.

15. The method of claim 13 wherein the calibration process comprises storing the optimal sampling phase in association with an identifier of the destination node.

16. The method of claim 13 wherein the calibration process comprises computing an offset between the determined optimal sampling phase and a target phase of the destination node.

17. The method of claim 13 wherein the calibration process comprises computing an offset between the determined optimal sampling phase and a target phase of the destination node and dividing the offset into a transmit phase adjustment and a receive phase adjustment and caching the transmit phase adjustment at the sending node and caching the receive phase adjustment at the destination node.

18. The method of claim 12 comprising triggering the calibration process if one or more of the following applies: if a specified time interval has elapsed, if a bit error rate of the recovered data is above a threshold, if a temperature of the destination node has changed, if a request for recalibration has been received from a user or from another node.

19. The method of claim 9 comprising:
using the interconnection medium to switch between pairs of the nodes in a time slotted manner;
operating the frequency synchronizing mechanism to synchronize a signal frequency of the plurality of nodes;
storing phase data relating to an amount of phase asynchrony and path characteristics between each of a plurality of pairs of the nodes;
using the stored data to adjust phase used by the nodes such that recovery of data is facilitated.

20. The method of claim 19 wherein the time slots of the interconnection medium have an interval which is of the same magnitude as a phase locking interval of a clock and data recovery process of at least one of the nodes with respect to the signal.
